(19) United States
(12) Patent Application Publication
(10) Pub. No.: US 2012/0080721 A1
(43) Pub. Date: Apr. 5, 2012

(54) SEMICONDUCTOR STRUCTURE AND METHOD FOR MAKING THE SAME

(76) Inventors: Chin-I Liao, Tai-Nan City (TW); Ching-I Li, Tainan City (TW); Shu-Yen Chan, Changhua County (TW)

(21) Appl. No.: 12/897,728

(22) Filed: Oct. 4, 2010

(51) Int. Cl. H01L 29/772; H01L 21/335

(52) U.S. Cl. 257/192; 438/285; 257/E29.242; 257/E21.403

(57) ABSTRACT

A semiconductor structure includes a recess disposed in a substrate, a non-doped epitaxial layer and a doped epitaxial layer. The non-doped epitaxial layer is disposed on the inner surface of the recess and substantially consists of Si and an epitaxial layer. The non-doped epitaxial layer has a sidewall and a bottom which together cover the inner surface. The bottom thickness is not greater than 120% of the sidewall thickness. The non-doped epitaxial layer and the doped epitaxial layer together fill up the recess.

### BACKGROUND OF THE INVENTION

1. Field of the Invention

The present invention generally relates to a composite epitaxial layer structure and a method for forming the composite epitaxial layer structure. In particular, the present invention is directed to a composite epitaxial layer structure including a doped epitaxial layer and a non-doped epitaxial layer and a method for forming the composite epitaxial layer structure to ensure a stable electric property of a gate channel.

2. Description of the Prior Art

In the process for manufacturing semiconductor elements, it is always a growing challenge for persons in the art to overcome, not only to constantly decrease the critical dimension but also to maintain the performance of the semiconductor elements. One of the challenges is to maintain the carriers, i.e. electrons and electron holes, to have sufficient carrier mobility. It is already known that the carrier mobility in the gate channel of a MOS, such as a P-MOS or an N-MOS, can be adjusted as long as a suitable stress is applied. One of the methods is to grow a strained P-type, such as SiGe:B, or an N-type, such as SiGe:As, doped epitaxial layer in recessed source/drain regions by means of a selective area epitaxial fashion.

Such approach is quite effective. On one hand a strained channel is constructed under the influence of an increased gate channel stress to increase the carrier mobility. On the other hand, the electric resistance of the source and the drain is also collaterally decreased. As to a circumstance of higher gate channel stress, a recessed source and drain of a particular shape will do. Although the recessed source and drain of a particular shape may further increase the stress on the gate channel, some adverse consequence, such as a short channel effect, happens when the dopant, such as B, in the doped epitaxial layer back diffuses into the gate channel.

In view of this, a novel method to form a composite epitaxial layer structure is still needed not only to block the back-diffusing of the dopant in the doped epitaxial layer but also to provide a sufficient gate channel stress.

### SUMMARY OF THE INVENTION

The present invention as a result proposes a novel method to form a composite epitaxial layer structure. The composite epitaxial layer structure made by the method of the present invention is not only able to block the back-diffusing of the dopant in the doped epitaxial layer, but also able to provide a sufficient gate channel stress. Accordingly, the composite epitaxial layer structure made by the method of the present invention is a total solution to fundamentally provide a sufficient gate channel stress.

The present invention in a first aspect proposes a semiconductor structure. The semiconductor structure of the present invention includes a substrate, a gate structure, a source and a drain, a non-doped epitaxial layer and a doped epitaxial layer. The gate structure is disposed on the substrate. The source and the drain are respectively disposed in the substrate and adjacent to the gate structure. At least one of the source and the drain includes a recess disposed in the substrate. The non-doped epitaxial layer is disposed on the inner surface of the recess and substantially consists of Si and an epitaxial material. The non-doped epitaxial layer has a sidewall and a bottom which together cover the inner surface. The bottom thickness is not greater than 120% of the sidewall thickness. The doped epitaxial layer includes Si, the epitaxial material and a dopant and fills the recess. The doped epitaxial layer does not contact the substrate at all due to the segregation of the non-doped epitaxial layer. In one embodiment of the present invention, the doping concentration of the doped epitaxial layer is at least 100 times greater than that of the non-doped epitaxial layer.

The present invention in a second aspect proposes a method for forming a semiconductor structure. First, a substrate is provided. Second, a gate structure is formed on the substrate. Next, a plurality of recesses are form in the substrate and adjacent to the gate structure. Then, a non-doped epitaxial layer is formed on the inner surface of the recesses. The non-doped epitaxial layer substantially consists of Si and an epitaxial material and is free of a dopant. The non-doped epitaxial layer has a sidewall and a bottom and the bottom thickness is not greater than 120% of the sidewall thickness. Later, a doped epitaxial layer including Si, the epitaxial material and the dopant is formed and fills the recess. In one embodiment of the present invention, the ratio of the bottom thickness to the sidewall thickness may be between 0.83 and 1.20.

The present invention in a third aspect proposes a method for forming a semiconductor structure. First, a substrate is provided. Second, a plurality of recesses are formed in the substrate. Next, a precursor mixture is provided to form a non-doped epitaxial layer on the inner surface of the recesses. The precursor mixture includes a silicon precursor, an epitaxial material precursor and a hydrogen-halogen compound. The flow rate ratio of the silicon precursor to the epitaxial material precursor is greater than 1.7. Later, a doped epitaxial layer including Si, the epitaxial material and the dopant is formed and substantially fills up the recess. In one embodiment of the present invention, a gate structure is formed on the substrate so that the recesses are adjacent to the gate structure.

On one hand, due to the segregation of the non-doped epitaxial layer in the composite epitaxial layer structure of the present invention, the doped epitaxial layer does not contact the substrate at all, so the back-diffusing of the dopant in the doped epitaxial layer is blocked. On the other hand, non-doped epitaxial layer has a proper bottom to sidewall thickness ratio, so a sufficient gate channel stress is able to be induced to maintain the carriers in the gate channel to have sufficient carrier mobility.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 illustrate an example for making the semiconductor structure of the present invention.

FIGS. 6-10 illustrate another example for making the semiconductor structure of the present invention.

### DETAILED DESCRIPTION

The present invention provides a semiconductor structure and the method for making the same. The semiconductor structure of the present invention has a non-doped epitaxial layer sticking to a recess and serving as a buffer layer. The doped epitaxial layer may block the back-diffusing of the dopant in the doped epitaxial layer. Besides, the non-doped epitaxial layer has a proper thickness ratio so the stress generated by the doped epitaxial layer is not compromised.

The present invention in a first aspect provides a method for making a semiconductor structure. FIGS. 1-5 illustrate an example for making the semiconductor structure of the present invention. Please refer to FIG. 1. First, a substrate 101 is provided. The substrate 101 is usually a semiconductor material, such as Si of a single crystal structure. Second, a gate structure 110 is formed on the substrate 101. The gate structure 110 may be formed on the substrate 101 by any conventional method, so that the gate structure 110 includes a gate conductive layer 111, a gate dielectric layer 112 and a spacer 113.

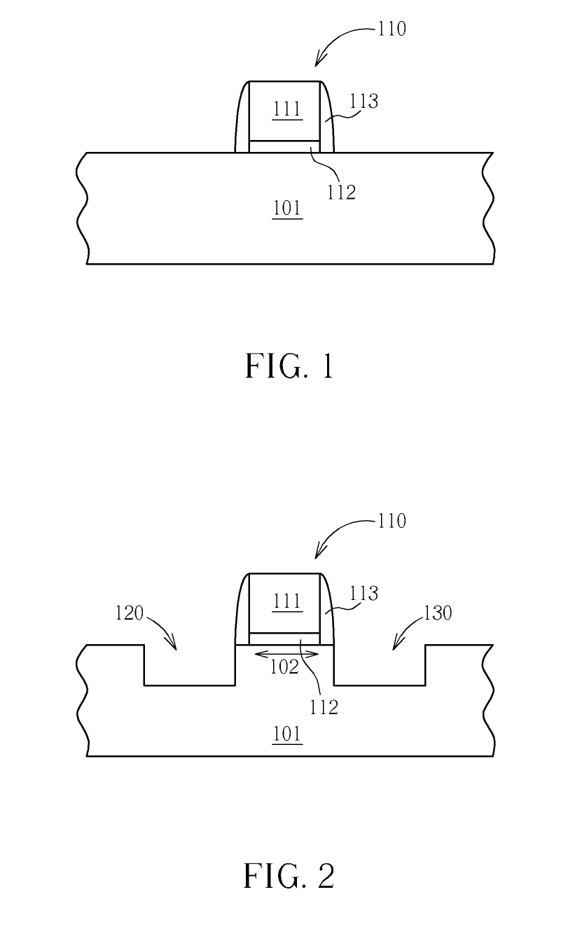

Next, please refer to FIG. 2. Multiple recesses 120/130 are formed in the substrate 101 so that the recesses 120/130 are adjacent to the gate structure 110. The recesses 120/130 which are adjacent to the gate structure 110 may be formed by any conventional method. How a proper shape and depth of the recesses 120/130 facilitate to induce a sufficient gate channel stress is common knowledge to persons in this art and the details will not be described here. In such a way, a gate channel 102 is formed between the recesses 120/130 in the substrate 101 and under the gate structure 110. To be followed, a suitable epitaxial material is wanted to fill the recesses 120/130 to influence the carrier mobility of the carriers in the gate channel.

Optionally, at least one of the recesses 120/130 may extend outwards, for example, to and under the gate conductive layer 111, or even further to and under the spacer 113, and overlaps with the gate conductive layer 111 or even with the spacer 113. The extending recesses 120/130 may be formed by first anisotropically etching the substrate then followed by isotropically etching the substrate to perform a lateral etching.

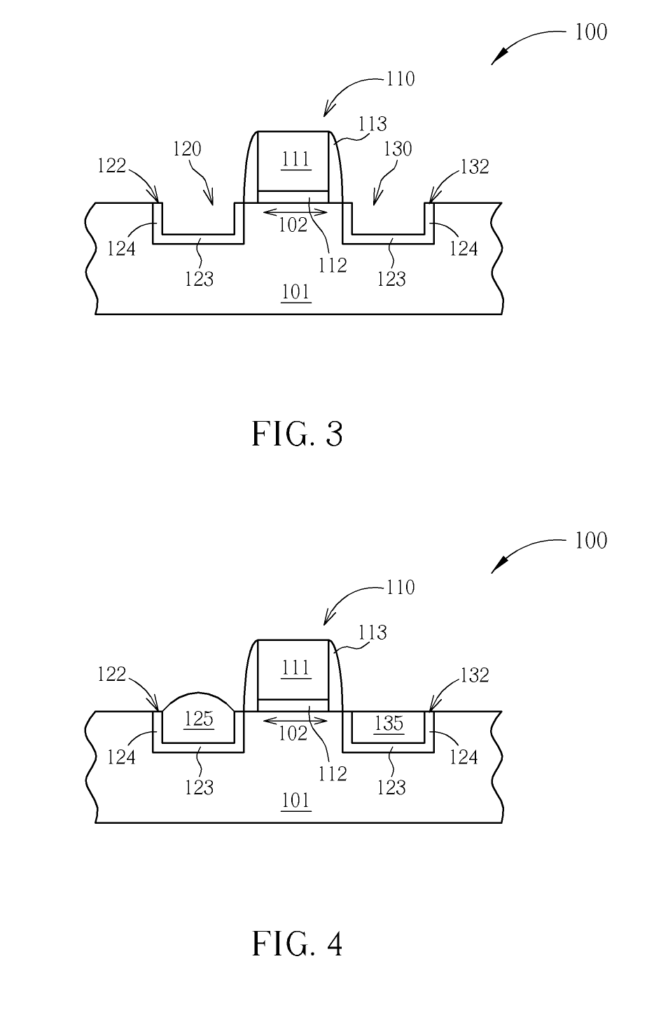

Then, as shown in FIG. 3, a non-doped epitaxial layer 122/132 is first formed in the recesses 120/130 and on the inner surface 121/131 of the recesses 120/130 by such as a selective area epitaxial method. In this embodiment, the resultant non-doped epitaxial layer 122/132 also has a bottom 123/133 and a sidewall 124/134 to follow the contour of the recesses 120/130 because the recesses 120/130 each have a bottom and a sidewall. One feature of the semiconductor structure 100 of the present invention resides in that the bottom thickness is not greater than 120% of the sidewall thickness. In one preferred embodiment of the present invention, the ratio of the bottom thickness to the sidewall thickness may be between 0.83 and 1.20. The resultant non-doped epitaxial layer 122/132 may be in a form of an open box.

The non-doped epitaxial layer 122/132 substantially consists of Si and an epitaxial material. Preferably, the non-doped epitaxial layer 122/132 is free of a dopant. The epitaxial material may be multivalent atoms larger or smaller than silicon, such as at least one of Ge, C, Ga, Sn and Pb. The non-doped epitaxial layer 122/132 may be formed by a conventional method. For example, the non-doped epitaxial layer 122/132 is formed by an epitaxial method using a suitable silicon precursor and a suitable epitaxial material precursor to form a non-doped epitaxial layer 122/132 in the recesses 120/130 and on the inner surface of the recesses 120/130. Please notice that the non-doped epitaxial layer 122/132 does not completely fill up the recesses 120/130.

Later, please refer to FIG. 4, an epitaxial layer is again formed within the recesses 120/130. The epitaxial layer is a doped epitaxial layer 125/135. The difference between the non-doped epitaxial layer 122/132 and the doped epitaxial layer 125/135 is that the doped epitaxial layer 125/135 further includes at least a dopant in addition to Si and the above-mentioned epitaxial material. The dopant may be multivalent atoms with valence electrons other than those of Si, depending on a P-MOS or an N-MOS element, such as boron. Although the non-doped epitaxial layer 122/132 is preferably free of a dopant, the original non-doped epitaxial layer 122/132 is still possibly contaminated by dopants owing to other reasons, such as in direct contact with the dopant-containing doped epitaxial layer 125/135. Nevertheless, the dopant concentration in the non-doped epitaxial layer 122/132 should be as small as possible so that the doping concentration of the doped epitaxial layer 125/135 is at least 100 times greater than that of the non-doped epitaxial layer 122/132.

For example, a suitable silicon precursor, a suitable epitaxial material precursor and a dopant are provided, so the doped epitaxial layer 125/135 is formed by an epitaxial method to fill the recesses 120/130. In accordance with different procedures, the dopant concentration in the doped epitaxial layer 125/135 may have different embodiments as well. For example, the doped epitaxial layer 125/135 may have a fixed doping concentration. Or, the doped epitaxial layer 125/135 may have a gradient doping concentration distribution. Although the doped epitaxial layer 125/135 is disposed within the recesses 120/130 and in direct contact with the non-doped epitaxial layer 122/132, the doped epitaxial layer 125/135 does not directly contact the substrate 101 at all due to the segregation of the non-doped epitaxial layer 122/132.

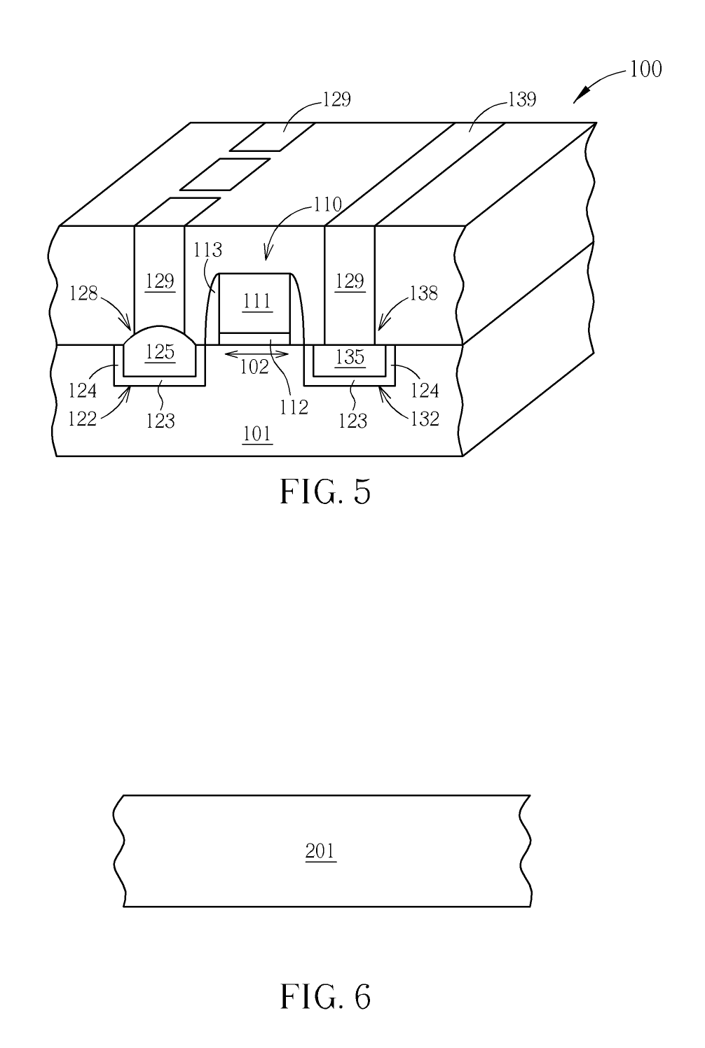

Optionally, the semiconductor structure 100 may include an etching-stop layer (not shown). In addition, the non-doped epitaxial layer 122/132 and the doped epitaxial layer 125/135 may continue to be converted to become a set of source 128 and drain 138. Later a silicide may be selectively formed on the surface of the source 128 and the drain 138, and a source contact plug 129 and a drain contact plug 139 are formed on the source 128 and the drain 138 to serve as the electric connection of the source 128 and the drain 138, as shown in FIG. 5. The shape of the source contact plug 129 and the drain contact plug 139 may be various, for example a single square or a slot. In one embodiment of the present invention, the shape of the source contact plug 129 and the drain contact plug 139 may be different. For example one is in a shape of a slot and the other is a shape of a single square.

The present invention in a second aspect provides another method for making a semiconductor structure. FIGS. 6-10 illustrate another example for making the semiconductor structure of the present invention. Please refer to FIG. 6. First, a substrate 201 is provided. The substrate 201 is usually a semiconductor material, such as Si of a single crystal structure. Optionally, there may be a gate structure on the substrate 101. The gate structure may include a gate conductive layer, a gate dielectric layer and a spacer. However, the substrate 101 may be free of a gate structure. The present invention may be applied in an epitaxial method.

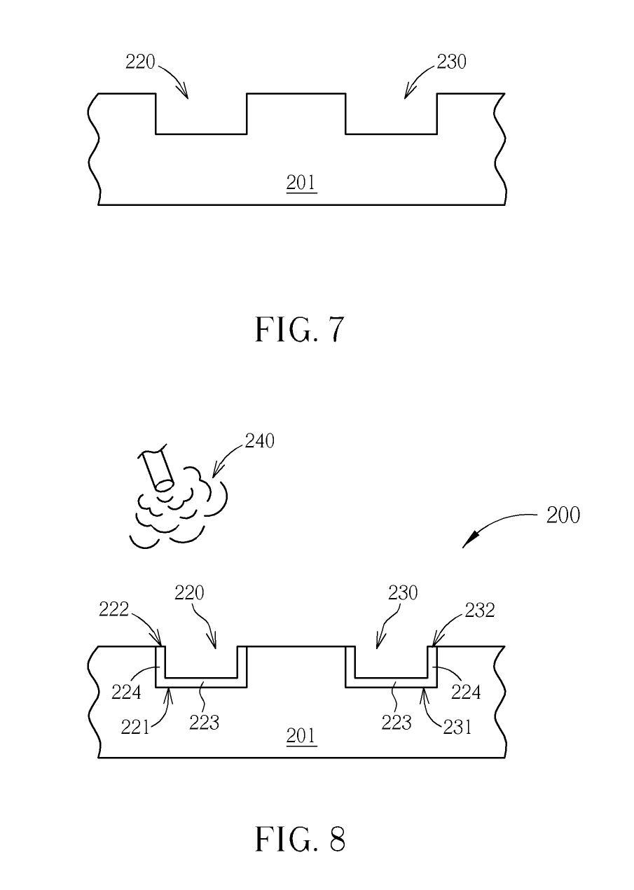

Next, please refer to FIG. 7. Multiple recesses 220/230 are formed in the substrate 201. The recesses 220/230 may be formed by any conventional methods, such as etching. To be followed, a suitable epitaxial material is wanted to fill the recesses 220/230.

Then, as shown in FIG. 8, a non-doped epitaxial layer 222/232 is first formed in the recesses 220/230 and on the inner surface of the recesses 220/230 by such as a selective area epitaxial method. The resultant non-doped epitaxial layer 222/232 has a bottom 223/233 and a sidewall 224/234 to follow the contour of the recesses 220/230. The resultant non-doped epitaxial layer 222/232 may be in a form of an open box.

The following steps may be used to render the bottom 223/233 and the sidewall 224/234 of the non-doped epitaxial layer 222/232 to have a proper thickness ratio. For example, a precursor mixture 240 is provided to form the non-doped epitaxial layer 222/232 on the inner surface 221/231 of the recesses 220/230 by an epitaxial method. The precursor mixture 240 may include various components. Foe example, the precursor mixture 240 may include a silicon precursor, an epitaxial material precursor and a hydrogen-halogen compound. The silicon precursor may include dichlorosilane. The epitaxial material precursor may include multivalent atoms larger or smaller than silicon, such as at least one of Ge, C, Ga, Sn and Pb. The hydrogen-halogen compound may be hydrogen chloride. Another feature of the present invention lies in the flow rate ratio of the silicon precursor to the epitaxial material precursor to be greater than 1.7.

Because the precursor mixture 240 is dopant-free, the resultant non-doped epitaxial layer 222/232 is supposed to be dopant-free, too. Please notice that the resultant non-doped epitaxial layer 222/232 does not fill up the recesses 220/230 completely. In one preferred embodiment of the present invention, the ratio of the bottom thickness to the sidewall thickness of the resultant non-doped epitaxial layer 222/232 may be between 0.83 and 1.20.

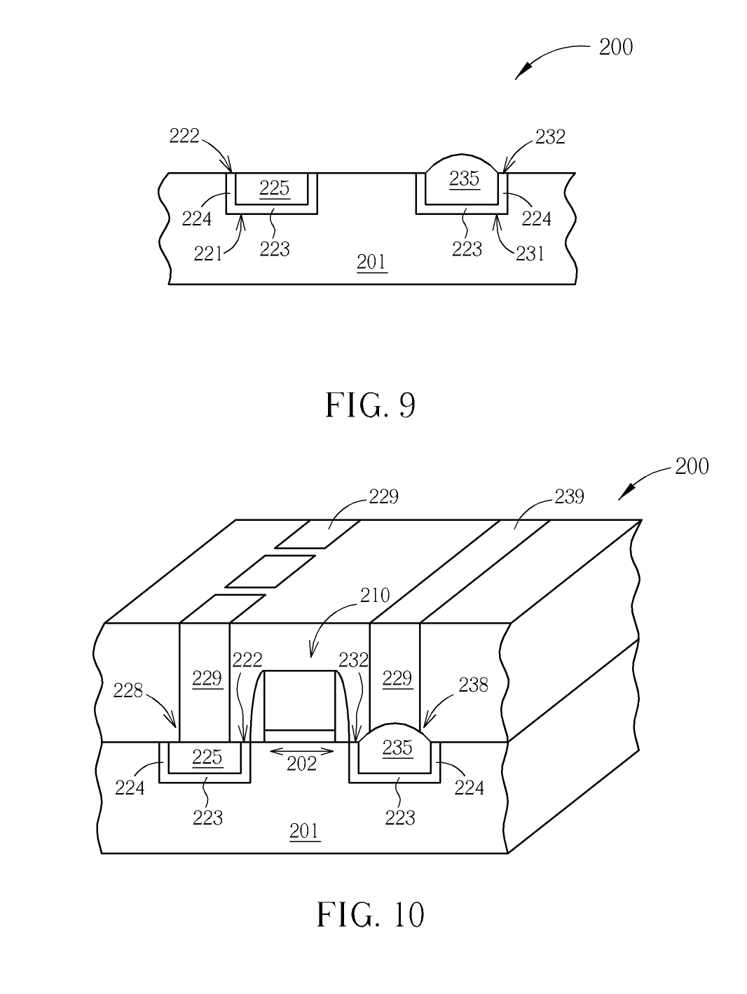

Later, please refer to FIG. 9, another epitaxial layer is again formed within the recesses 220/230. The epitaxial layer is a doped epitaxial layer 225/235. The difference between the non-doped epitaxial layer 222/232 and the doped epitaxial layer 225/235 is that the doped epitaxial layer 225/235 further includes at least a dopant in addition to Si and the above-mentioned epitaxial material. The dopant may be multivalent atoms with valence electrons other than those of Si, depending on a P-MOS or an N-MOS element, such as boron. Although the non-doped epitaxial layer 222/232 is preferably free of a dopant, the original non-doped epitaxial layer 222/232 is still possibly contaminated by dopants owing to other reasons, such as in direct contact with the dopant-containing doped epitaxial layer 225/235. Nevertheless, the dopant concentration in the non-doped epitaxial layer 222/232 should be as small as possible so that the doping concentration of the doped epitaxial layer 225/235 is at least 100 times greater than that of the non-doped epitaxial layer 222/232.

For example, a suitable silicon precursor, a suitable epitaxial material precursor and a dopant are provided, so the doped epitaxial layer 225/235 is formed by any proper conventional method, such as an epitaxial method to fill the recesses 220/230. In accordance with different procedures, the dopant concentration in the doped epitaxial layer 225/235 may have different embodiments as well. For example, the doped epitaxial layer 225/235 may have a fixed doping concentration. Or, the doped epitaxial layer 225/235 may have a gradient doping concentration distribution. Although the doped epitaxial layer 225/235 is disposed within the recesses 220/230 and in direct contact with the non-doped epitaxial layer 222/232, the doped epitaxial layer 225/235 does not directly contact the substrate 201 at all due to the segregation of the non-doped epitaxial layer 222/232.

Optionally, the semiconductor structure 200 may include an etching-stop layer (not shown). Please refer to FIG. 10. If there is a gate structure 210 on the substrate 201, the non-doped epitaxial layer 222/232 and the doped epitaxial layer 225/235 may continue to be converted to become a set of source 228 and drain 238 and a gate channel 202 is right between the source 228 and the drain 238. A silicide may be selectively formed on the surface of the source 228 and the drain 238, and a source contact plug 229 and a drain contact plug 239 are formed on the source 228 and the drain 238 to serve as the electric connection of the source 228 and the drain 238. The shape of the source contact plug 229 and the drain contact plug 239 may be various, for example a single square or a slot. In one embodiment of the present invention, the shape of the source contact plug 229 and the drain contact plug 239 may be different. For example one is in a shape of a slot and the other is a shape of a single square.

After the previous steps, a semiconductor structure is consequently obtained. FIG. 5 illustrates an example of the semiconductor structure of the present invention. FIG. 10 illustrates another example of the semiconductor structure of the present invention. The embodiment of FIG. 5 is taken for example for the following descriptions. In the semiconductor structure 100 of the present invention, the gate structure 110 is disposed on the substrate 101. The source 128 and the drain 138 are respectively disposed in the substrate 101 and adjacent to the gate structure 110. Optionally, there may be an etching-stop layer (not shown) in the semiconductor structure 100.

The source 128 and the drain 138 may have a recessed or bulging structure, so at least one of the source 128 and the drain 138 includes a recess 120/130 disposed in the substrate 101. The recess 120/130 may include two different epitaxial layers, such as a non-doped epitaxial layer 122/132 and a doped epitaxial layer 125/135. The shapes and chemical compositions of the non-doped epitaxial layer 122/132 and the doped epitaxial layer 125/135 are different.

The non-doped epitaxial layer 122/132 is disposed on the inner surface 121/131 of the recess 120/130 and covers the inner surface 121/131. The non-doped epitaxial layer 122/132 has a sidewall 124/134 and a bottom 123/133. One feature of the present invention resides in that the bottom 123/133 thickness is not greater than 120% of the sidewall 124/134 thickness. In one preferred embodiment of the present invention, the ratio of the bottom thickness to the sidewall thickness may be between 0.83 and 1.20. The resultant non-doped epitaxial layer 122/132 may be in a form of an open box.

The non-doped epitaxial layer 122/132 substantially consists of Si and an epitaxial material. Preferably, the non-doped epitaxial layer 122/132 is free of a dopant. The epitaxial material may be multivalent atoms larger or smaller than silicon, such as at least one of Ge, C, Ga, Sn and Pb. Please notice that the non-doped epitaxial layer 122/132 does not completely fill up the recesses 120/130.

The doped epitaxial layer 125/135 fills up the recess 120/130. FIG. 5 illustrates a surface of the doped epitaxial layer is higher than the surface of the substrate 101. The difference between the non-doped epitaxial layer 122/132 and the doped epitaxial layer 125/135 is that the doped epitaxial layer 125/135 further includes at least a dopant in addition to Si and the above-mentioned epitaxial material. The dopant may be multivalent atoms with valence electrons other than those of Si, depending on a P-MOS or an N-MOS element, such as boron.

Although the non-doped epitaxial layer 122/132 is preferably free of a dopant, the original non-doped epitaxial layer 122/132 is still possibly contaminated by dopants owing to other reasons, such as in direct contact with the dopant-containing doped epitaxial layer 125/135. Nevertheless, the dopant concentration in the non-doped epitaxial layer 122/132 should be as small as possible so that the doping concentration of the doped epitaxial layer 125/135 is at least 100 times greater than that of the non-doped epitaxial layer 122/132.

In accordance with different embodiments, the dopant concentration in the doped epitaxial layer 125/135 may be different. For example, the doped epitaxial layer 125/135 may have a fixed doping concentration. Or, the doped epitaxial layer 125/135 may have a gradient doping concentration distribution. Although the doped epitaxial layer 125/135 is disposed within the recesses 120/130 and in direct contact with the non-doped epitaxial layer 122/132, the doped epitaxial layer 125/135 does not directly contact the substrate 101 at all due to the segregation of the non-doped epitaxial layer 122/132 so the back-diffusing of dopants can be blocked.

Optionally, the non-doped epitaxial layer 122/132 and the doped epitaxial layer 125/135 may be the source 128 and drain 138 of the gate structure 110. There is a gate channel 102 between the source 128 and drain 138, under the gate structure 110 and in the substrate 101. Besides, a silicide may be selectively formed on the surface of the source 128 and the drain 138. Furthermore, a source contact plug 129 and a drain contact plug 139 are formed on the source 128 and the drain 138 to serve as the electric connection of the source 128 and the drain 138, as shown in FIG. 5. The shape of the source contact plug 129 and the drain contact plug 139 may be various, for example a single square or a slot. In one embodiment of the present invention, the shape of the source contact plug 129 and the drain contact plug 139 may be different. For example one is in a shape of a slot and the other is a shape of a single square. If the substrate is free of a gate structure, the example is illustrated in FIG. 9.

Those skilled in the art will readily observe that numerous modifications and alterations of the device and method may be made while retaining the teachings of the invention.

What is claimed is:

1. A semiconductor structure, comprising:
a substrate;
a gate structure disposed on said substrate;
a source disposed in said substrate and adjacent to said gate structure; and
a drain disposed in said substrate and adjacent to said gate structure, wherein at least one of said source and said drain comprises;
a recess disposed in said substrate;
a non-doped epitaxial layer disposed on the inner surface of said recess and substantially consisting of Si and an epitaxial material, said non-doped epitaxial layer having a sidewall and a bottom which together cover the inner surface, wherein the bottom thickness is not greater than 120% of the sidewall thickness; and
a doped epitaxial layer comprising Si, said epitaxial material and a dopant and filling said recess, where said doped epitaxial layer does not contact said substrate at all due to the presence of said non-doped epitaxial layer.

2. The semiconductor structure of claim 1, wherein a ratio of the bottom thickness to the sidewall thickness is between 0.83 and 1.20.

3. The semiconductor structure of claim 1, wherein a doping concentration of said doped epitaxial layer is at least 100 times greater than that of said non-doped epitaxial layer.

4. The semiconductor structure of claim 1, wherein the surface of said doped epitaxial layer is higher than that of said substrate.

5. The semiconductor structure of claim 1, wherein said substrate comprises Si.

6. The semiconductor structure of claim 1, further comprising:
a source contact plug disposed above said source; and
a drain contact plug disposed above said drain, wherein one of said source contact plug and said drain contact plug is in a shape of a slot and the other is a shape of a single square.

7. The semiconductor structure of claim 1, wherein said epitaxial material comprises at least one of Ge, C, Ga, Sn and Pb.

8. A method for forming a semiconductor structure, comprising:
providing a substrate;
forming a gate structure on said substrate;
forming a plurality of recesses in said substrate and adjacent to said gate structure;
forming a non-doped epitaxial layer disposed on the inner surface of said recesses, substantially consisting of Si and an epitaxial material and free of a dopant, said non-doped epitaxial layer having a sidewall and a bottom, wherein the bottom thickness is not greater than 120% of the sidewall thickness; and
forming a doped epitaxial layer comprising Si, said epitaxial material and said dopant and filling said recess.

9. The method for forming a semiconductor structure of claim 8, further comprising:
forming a source contact plug disposed above said source; and
forming a drain contact plug disposed above said drain, wherein one of said source contact plug and said drain contact plug is in a shape of a slot and the other is a shape of a single square.

10. The method for forming a semiconductor structure of claim 8, wherein a ratio of the bottom thickness to the sidewall thickness is between 0.83 and 1.20.

11. The method for forming a semiconductor structure of claim 8, wherein a doping concentration of said doped epitaxial layer is at least 100 times greater than that of said non-doped epitaxial layer.

12. The method for forming a semiconductor structure of claim 8, wherein said doped epitaxial layer has a gradient doping concentration.

13. The method for forming a semiconductor structure of claim 8, wherein said doped epitaxial layer has a fixed doping concentration.

14. The method for forming a semiconductor structure of claim 8, wherein said epitaxial material comprises at least one of Ge, C, Ga, Sn and Pb.

15. A method for forming a semiconductor structure, comprising:
providing a substrate;
forming a plurality of recesses in said substrate;
providing a precursor mixture to form a non-doped epitaxial layer on the inner surface of said recesses, said precursor mixture comprising a silicon precursor, an epitaxial material precursor and a hydrogen-halogen compound, wherein the flow rate ratio of said silicon precursor to said epitaxial material precursor is greater than 1.7; and
forming a doped epitaxial layer comprising Si, said epitaxial material and a dopant to substantially fill said recesses.

16. The method for forming a semiconductor structure of claim 15, further comprising:
forming a source contact plug disposed above said source; and
forming a drain contact plug disposed above said drain, wherein one of said source contact plug and said drain contact plug is in a shape of a slot and the other is a shape of a single square.

17. The method for forming a semiconductor structure of claim 15, wherein said non-doped epitaxial layer has a sidewall and a bottom and a ratio of the bottom thickness to the sidewall thickness is between 0.83 and 1.20.

18. The method for forming a semiconductor structure of claim 15, wherein a doping concentration of said doped epitaxial layer is at least 100 times greater than that of said non-doped epitaxial layer.

19. The method for forming a semiconductor structure of claim 15, wherein said doped epitaxial layer has a fixed doping concentration.

20. The method for forming a semiconductor structure of claim 15, wherein said doped epitaxial layer has a gradient doping concentration.

21. The method for forming a semiconductor structure of claim 15, wherein said epitaxial material precursor comprises at least one of Ge, C, Ga, Sn and Pb.

22. The method for forming a semiconductor structure of claim 15, wherein said silicon precursor comprises dichlorosilane.
